(19) United States
(12) Patent Application Publication
(10) Pub. No.: US 2024/0348238 A1
(43) Pub. Date: Oct. 17, 2024

(54) CMOS inverter circuit

(71) Applicant: Hoseo University Academic Cooperation Foundation, Asan-si (KR)

(72) Inventors: Byung-Seong BAE, Suwon-si (KR); Eui-Joong YUN, Seoul (KR); Je-Hun YOE, Hwaseong-si (KR); Seo-Jin KANG, Siheung-si (KR); Hyuck-Su LEE, Incheon (KR); Jae-Geun WOO, Cheonan-si (KR)

(21) Appl. No.: 18/751,562

(22) Filed: Jun. 24, 2024

Related U.S. Application Data
(63) Continuation of application No. PCT/KR2022/016895, filed on Nov. 1, 2022.

(30) Foreign Application Priority Data
Dec. 24, 2021 (KR) 10-2021-0187440

(51) Int. Cl. H03K 3/356

(52) U.S. Cl. CPC H03K 3/356113

(57) ABSTRACT

A CMOS inverter circuit includes a first and second PMOS transistor connected in series to a power supply voltage (VDD) and a first NMOS transistor connected in series with the second PMOS transistor and to ground (GND). All transistors receive the same input signal.

This configuration enables normal logic gate operation even when the P-channel characteristics of the PMOS transistors are shifted. The channel widths of the first and second PMOS transistors can be varied to adjust circuit performance.

### BACKGROUND OF THE INVENTION

### 1. Field of the Invention

The present invention relates to an inverter circuit, and more particularly, to a CMOS inverter circuit that can operate normally even when the characteristics of a PMOS transistor are shifted to the right.

### 2. Description of the Related Art

Modern society is a digital age and digital signals are widely used. In the processing of digital signals, digital circuits are used, and among these digital circuits, the inverter is a fundamental logic gate. Digital signals consist of only two values, 0 and 1. An inverter outputs 1 for an input of 0 and outputs 0 for an input of 1.

FIG. 1 is a schematic diagram of an inverter circuit using a CMOS transistor circuit. Referring to FIG. 1, the inverter circuit includes a P-channel MOS transistor (P1) with its source terminal connected to the power supply voltage (Vdd) and an N-channel MOS transistor (N1) with its source terminal connected to the ground (GND). The P-channel MOS transistor (P1) and the N-channel MOS transistor (N1) are connected in series, and their gate terminals are connected to each other. The input voltage (Vin) applied through the gate terminal is inverted and output to the output terminal (Vout).

FIG. 2 illustrates the output voltage (Vout) versus input voltage (Vin) graph of the CMOS inverter circuit, where the input voltage (Vin) is increased from 0V to the power supply voltage VDD. When the input voltage (Vin) of the CMOS inverter is applied in a low state, the output voltage (Vout) is output in a high state. Conversely, when the input voltage (Vin) is applied in a high state, the output voltage (Vout) is inverted and output in a low state. In other words, if the power supply voltage VDD is considered as logic 1 and 0V as logic 0, when the input is 0 (0V), the P-channel MOS transistor (P1) turns on (ON) and the N-channel MOS transistor (N1) turns off (OFF), resulting in an output voltage of VDD (logic 1). On the other hand, when the input is 1 (VDD), the P-channel MOS transistor (P1) turns off (OFF) and the N-channel MOS transistor (N1) turns on (ON), resulting in an output voltage of 0V (logic 0).

Such CMOS circuits are composed of thin-film transistors (TFTs), which can be configured using P-channel and N-channel TFTs. Thin-film transistors utilizing oxide materials are fabricated on glass substrates and applied to OLED TVs, among other devices. Scan drivers are also implemented using oxide thin-film transistors. However, typical oxide transistors are primarily well-fabricated as N-channel types, leading to circuits mainly composed of N-channel transistors. This makes it difficult to configure CMOS inverters, which require both N-channel and P-channel transistors.

Thus, continuous research is being conducted on P-channel oxide transistors. FIGS. 3A and 3B respectively show the output characteristics (a) and transfer characteristics (b) of the first bottom-gate P-channel oxide TFT utilizing a Cu₂O thin film. According to FIGS. 3A and 3B, the first P-channel oxide TFT had a Cu₂O thin film deposited at room temperature and was post-annealed at 200° C. after fabrication, resulting in electrical characteristics with a field-effect mobility (μ_{FE}) of 1.2×10⁻³ cm²/Vs, an on/off current ratio (Iₒₙ/I_{oft}) of 2×10³, and a threshold voltage (Vth) of −12V.

However, as shown in FIGS. 4A and 4B, it can be observed that the characteristics of the P-channel type of the oxide thin-film transistor have shifted to the right. This means that when the gate voltage is 0, the current is not 0. In such cases, the normal operation of the inverter's logic gate characteristic, which outputs 1 for an input of 0 and outputs 0 for an input of 1 for digital signals, becomes difficult to achieve.

### SUMMARY OF THE INVENTION

The present invention has been devised to solve such problems, and its purpose is to provide a CMOS inverter circuit that can operate normally even when the P-channel characteristics have shifted to the right.

In order to solve such problems, there is provided a CMOS inverter circuit comprising: a first PMOS transistor, having a gate terminal for receiving an input signal and a source terminal connected to a power supply voltage (VDD); a second PMOS transistor, having a gate terminal for receiving the same input signal as the first PMOS transistor, and having a source terminal connected in series with a drain terminal of the first PMOS transistor; and a first NMOS transistor, connected in series with the drain terminal of the second PMOS transistor, having a gate terminal for receiving the same input signal as the first and second PMOS transistors, and having a source terminal connected to ground (GND).

Preferably, the channel width of the first PMOS transistor is different from the channel width of the second PMOS transistor.

The CMOS inverter circuit may further comprise a second NMOS transistor connected to a node P, wherein the node P is a node where the drain of the first PMOS transistor and the source of the second PMOS transistor are connected in series.

Preferably, a drain of the second NMOS transistor is connected to the node P and a source of the second NMOS transistor is connected to ground (GND).

The input voltage applied to a gate terminal of the second NMOS transistor may be the same as the input voltage of the first NMOS transistor.

According to the present invention, there is an effect of enabling normal logic gate operation of a CMOS inverter circuit even when the characteristics of the PMOS transistor are shifted to the right.

### BRIEF DESCRIPTION OF THE DRAWINGS

FIG. 1 is a circuit diagram of an inverter using a CMOS transistor circuit.

FIG. 2 is a graph showing the output voltage (Vout) with respect to the input voltage (Vin) of the CMOS inverter circuit.

FIG. 3A is a graph showing the output characteristics of the first bottom-gate P-channel oxide TFT utilizing a Cu₂O thin film.

FIG. 3B is a graph showing the transfer characteristics of the first bottom-gate P-channel oxide TFT utilizing a Cu₂O thin film.

FIGS. 4A and 4B are graphs showing the transfer characteristics of P-channel oxide TFTs, illustrating that the P-channel characteristics of the oxide thin-film transistors are shifted to the right.

FIG. 5 is a circuit diagram illustrating the first embodiment of the CMOS inverter circuit according to the present invention.

FIG. 6 is a circuit diagram illustrating the second embodiment of the CMOS inverter circuit according to the present invention.

FIG. 7 is a graph showing the output voltage (Vout) with respect to the input voltage (Vin) of the CMOS inverter circuit according to the present invention.

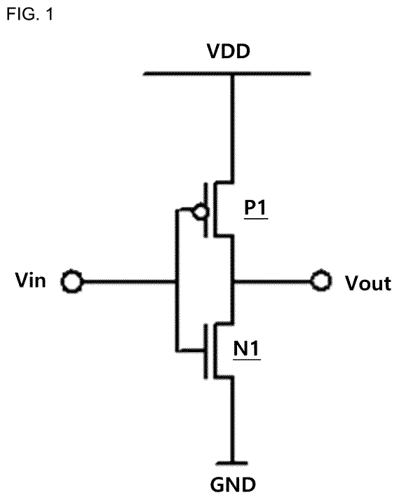

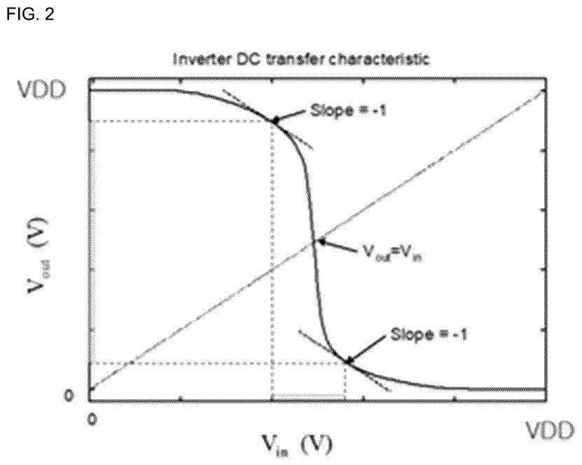

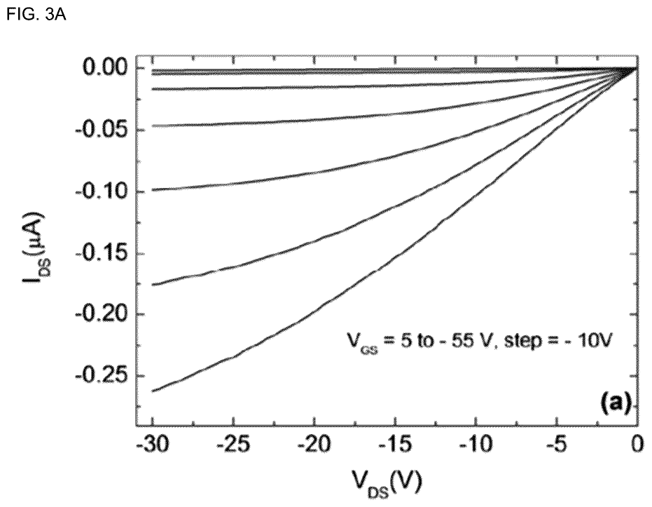

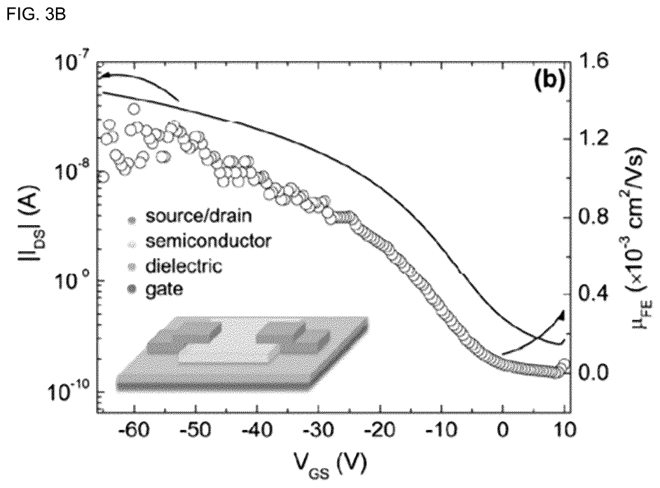

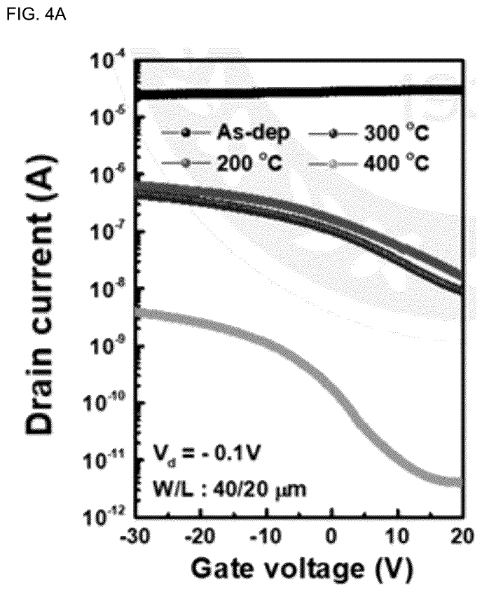

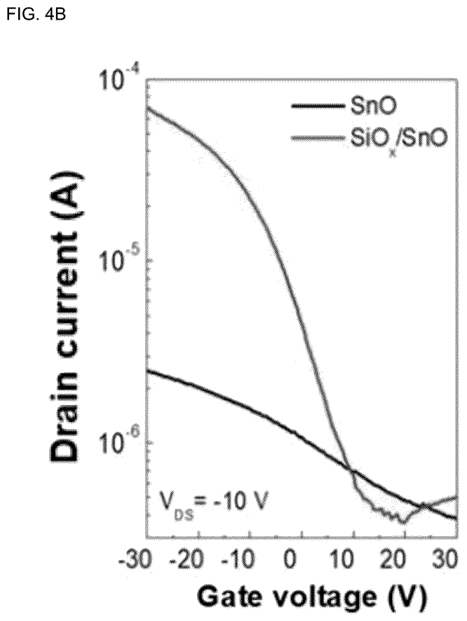

### DETAILED DESCRIPTION OF THE INVENTION

Hereinafter, a preferred embodiment of the present invention will be described in detail with reference to the accompanying drawings. It should be noted that the terms and words used in this specification and claims are not to be construed in their ordinary or dictionary sense, but rather in a sense and concept consistent with the technical idea of the invention, based on the principle that the inventor may properly define the concept of a term to best describe his invention. Therefore, the embodiments described in this specification and the configurations shown in the drawings are only preferred examples of the present invention and do not represent all the technical aspects of the invention. Thus, it should be understood that there may be various equivalents and modifications that can replace them at the time of this application.

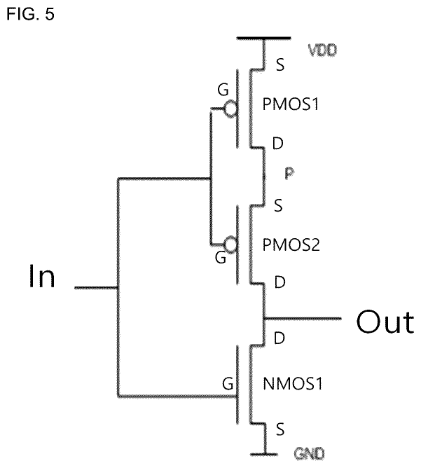

FIG. 5 is a schematic diagram illustrating a first embodiment of a CMOS inverter circuit according to the present disclosure.

Referring to FIG. 5, the CMOS inverter circuit according to the first embodiment of the present invention includes: a first PMOS transistor (PMOS1) with its source terminal connected in series to the power supply voltage (VDD), and a second PMOS transistor (PMOS2) connected in series with the first PMOS transistor (PMOS1), both of which receive the same input signal (In) through their gate terminals; and a first NMOS transistor (NMOS1) connected in series with the second PMOS transistor (PMOS2), which also receives the same input signal (In) through its gate terminal as the PMOS transistors, and has its source terminal connected to the ground.

Here, the voltage at point P, which is between the drain of the first PMOS transistor (PMOS1) and the source of the second PMOS transistor (PMOS2) in FIG. 5, is less than the power supply voltage (VDD) applied to the source of the first PMOS transistor (PMOS1) and less than the gate input's power supply voltage (VDD). As a result, the VGS (gate-to-source voltage) of the second PMOS transistor (PMOS2) is not zero but rather a value greater than zero, causing it to turn off. Additionally, by varying the channel widths of the first PMOS transistor (PMOS1) and the second PMOS transistor (PMOS2), the voltage at point P can be adjusted.

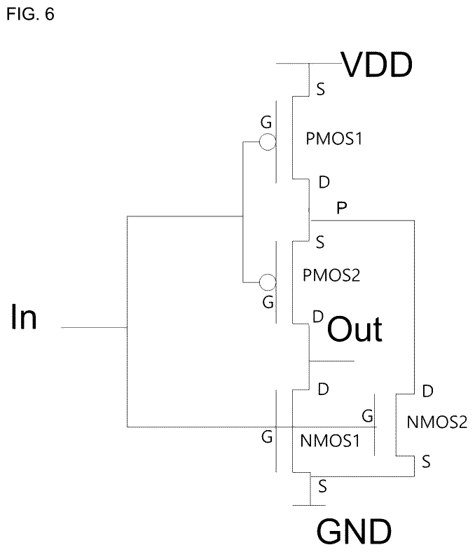

FIG. 6 is a schematic diagram illustrating a second embodiment of a CMOS inverter circuit according to the present invention.

Referring to FIG. 6, the CMOS inverter circuit according to the second embodiment of the present invention includes: a first PMOS transistor (PMOS1) with its source terminal connected in series to the power supply voltage (VDD), and a second PMOS transistor (PMOS2) connected in series with the first PMOS transistor (PMOS1), both of which receive the same input signal (In) through their gate terminals; a first NMOS transistor (NMOS1) connected in series with the second PMOS transistor (PMOS2), which also receives the same input signal (In) through its gate terminal as the PMOS transistors, and has its source terminal connected to the ground; and a second NMOS transistor (NMOS2) connected to the node P, which is the point where the drain of the first PMOS transistor (PMOS1) and the source of the second PMOS transistor (PMOS2) are connected in series.

At this time, the drain of the second NMOS transistor (NMOS2) is connected to the node P, the source is connected to the ground, and the input voltage applied to the gate terminal of the second NMOS transistor (NMOS2) is the same as the input voltage (In) of the first NMOS transistor (NMOS1).

In the second embodiment of the present invention as shown in FIG. 6, when the gate input is 0, the N-channel transistors, namely the first NMOS transistor (NMOS1) and the second NMOS transistor (NMOS2), are turned off, and the P-channel transistors, namely the first PMOS transistor (PMOS1) and the second PMOS transistor (PMOS2), are turned on, resulting in the output being the power supply voltage (VDD). When the gate input is VDD, point P is connected to the ground by the N-channel transistors, the first NMOS transistor (NMOS1) and the second NMOS transistor (NMOS2), lowering the voltage at point P to ground. This increases the voltage difference between the gate voltage of the P-channel transistors and the source electrode of the second PMOS transistor (PMOS2), ensuring that the P-channel transistors, the first PMOS transistor (PMOS1) and the second PMOS transistor (PMOS2), are definitively turned off. This improves the inverter characteristics.

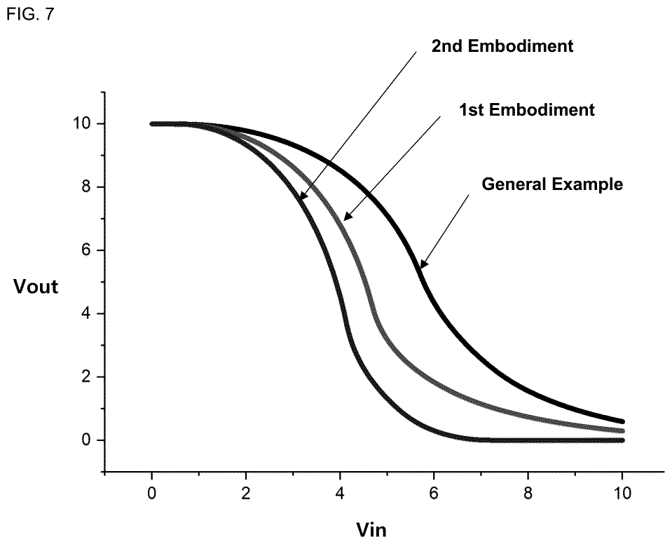

FIG. 7 is a graph illustrating the output voltage (Vout) versus input voltage (Vin) of the CMOS inverter circuit according to the present invention. Compared to the characteristic curve of a typical CMOS inverter circuit (black line), the graphs of the first embodiment (red line) and the second embodiment (blue line) are shifted to the left. This demonstrates that the first and second embodiments of the present invention can enable the inverter to operate normally, overcoming the difficulties in normal operation caused by the rightward shift of the P-channel characteristics in the previously described CMOS inverter circuit.

As described above, although the present invention has been described by means of limited embodiments and drawings, the invention is not limited thereby, and various modifications and variations can be made by those having ordinary knowledge in the technical field to which the invention belongs, within the technical idea of the invention and the equitable scope of the claims of the patent, which will be described below.

What is claimed is:

1. A CMOS inverter circuit comprising:
a first PMOS transistor, having a gate terminal for receiving an input signal and a source terminal connected to a power supply voltage (VDD);
a second PMOS transistor, having a gate terminal for receiving the same input signal as the first PMOS transistor, and having a source terminal connected in series with a drain terminal of the first PMOS transistor; and
a first NMOS transistor, connected in series with the drain terminal of the second PMOS transistor, having a gate terminal for receiving the same input signal as the first and second PMOS transistors, and having a source terminal connected to ground (GND).

2. The CMOS inverter circuit of claim 1, wherein the channel width of the first PMOS transistor is different from the channel width of the second PMOS transistor.

3. The CMOS inverter circuit of claim 1, further comprising a second NMOS transistor connected to a node P, wherein the node P is a node where the drain of the first PMOS transistor and the source of the second PMOS transistor are connected in series.

4. The CMOS inverter circuit of claim 3, wherein a drain of the second NMOS transistor is connected to the node P and a source of the second NMOS transistor is connected to ground (GND).

5. The CMOS inverter circuit of claim 3, wherein the input voltage applied to a gate terminal of the second NMOS transistor is the same as the input voltage of the first NMOS transistor.
